(19) United States
(12) Patent Application Publication
(10) Pub. No.: US 2026/0109654 A1
(43) Pub. Date: Apr. 23, 2026

(54) STRUCTURAL MEMBER

(71) Applicant: TOTO LTD., Fukuoka (JP)

(72) Inventors: Shun KATAOKA, Fukuoka (JP); Senri SAKAMOTO, Fukuoka (JP); Ryoto TAKIZAWA, Fukuoka (JP)

(73) Assignee: TOTO LTD., Fukuoka (JP)

(21) Appl. No.: 19/317,974

(22) Filed: Sep. 3, 2025

(30) Foreign Application Priority Data
Oct. 18, 2024 (JP) 2024-184124

(51) Int. Cl. C04B 41/50; C04B 41/00; C04B 41/45; C04B 41/87

(52) U.S. Cl. CPC C04B 41/5045; C04B 41/009; C04B 41/4529; C04B 41/87

(57) ABSTRACT

A structural member 10 includes a substrate 100 and a passivation film 200 covering the surface of the substrate 100. The passivation film 200 includes lanthanum yttrium oxide as a main component.

This application is based upon and claims the benefit of priority from Japanese Patent Application No. 2024-184124, filed on Oct. 18, 2024, the entire contents of which are incorporated herein by reference.

### FIELD

The present invention relates to a structural member.

### BACKGROUND

Resistance (Durability) against plasma is required for members constituting a semiconductor manufacturing apparatus, for example, members such as chamber inner walls and the like. Therefore, structural members having a passivation film (protective film) formed on the surface of a substrate (base material) have been commonly used as the above members as disclosed in Japanese Translation of PCT International Application Publication No. 2019-507962. Oxide ceramics, such as yttria, are often used as passivation films.

### SUMMARY

The present inventors have been considering the use of a novel material as a material for passivation films and further improvement in the resistance of passivation film against plasma.

The present invention has been made in view of such problems and an object of the present invention is to provide a structural member having sufficient resistance against plasma.

To solve the above problem, the structural member of the present invention comprises a substrate and a passivation film covering the surface of the substrate. The passivation film comprises lanthanum yttrium oxide as a main component.

The experiments conducted by the present inventors have demonstrated that when a passivation film is formed by using a material comprising lanthanum yttrium oxide as a main component, a sufficient resistance of the passivation film against plasma can be achieved.

According to the present invention, a structural member with sufficient resistance against plasma can be provided.

### BRIEF DESCRIPTION OF THE DRAWINGS

FIG. 1 schematically illustrates a cross-section of the structural member;

FIG. 2 is a graph illustrating the relationship between the hexagonal crystal abundance ratio of the passivation film and the resistance of the passivation film against plasma;

FIG. 3 is a graph illustrating the relationship between the hexagonal crystal abundance ratio of the passivation film and the resistance of the passivation film against plasma;

FIG. 4 is a graph illustrating an analytical method using X-ray diffraction;

FIG. 5 is a graph illustrating an analytical method using X-ray diffraction; and

FIG. 6 is a table listing film-forming conditions and the like when forming a passivation film.

### DETAILED DESCRIPTION

Hereinafter the present embodiment will be described with reference to attached drawings. For clarity of description, identical reference numerals are used to denote the same elements in all figures, and redundant descriptions are omitted.

The structural member 10 of the present embodiment is configured as a member for a semiconductor manufacturing apparatus, such as a plasma etching apparatus. More specifically, the structural member 10 is a member used for the inner wall of a process chamber of semiconductor manufacturing apparatus. The use of the structural member 10 in the present embodiment is merely an example. The structural member 10 may be a member arranged within the process chamber of semiconductor manufacturing apparatus, such as a focus ring.

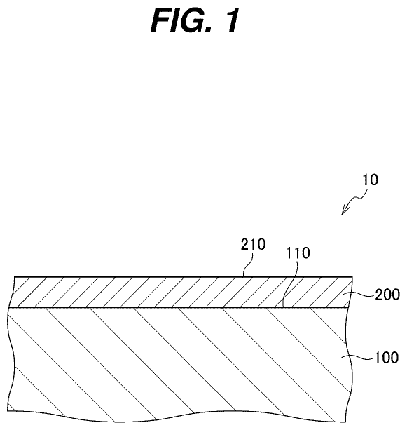

As shown in FIG. 1, the structural member 10 includes a substrate 100 and a passivation film 200. In a plasma etching apparatus or the like, the surface 210 of the passivation film 200 is exposed to the interior of the process chamber. The passivation film 200 is formed to protect the surface 110 of the substrate 100 from plasma.

The substrate 100 is a member forming the primary portion of the structural member 10. In the present embodiment, the substrate 100 is a sintered ceramic body including high-purity aluminum oxide (Al₂O₃), but may be a different ceramic material or member other than a non-ceramic material (for example, a metal member). The surface 110 of the substrate 100 is flat in the present embodiment, but may be curved or tapered in portions.

The passivation film 200 is formed to protect the substrate 100 from plasma as described above. The passivation film 200 is formed to cover the entire surface 110 of the substrate 100. The passivation film 200 is composed of a material including lanthanum yttrium oxide as a main component. Lanthanum yttrium oxide described above is, for example, LaYO₃. The ratio among the number of lanthanum (La) atoms, the number of yttrium (Y) atoms and the number of oxygen (O) atoms in the passivation film 200 may be different from the ratio described above. The passivation film 200 of the present embodiment is formed by using an aerosol deposition method, but may be formed by another film-forming method.

As used herein, the “main component” refers to the compound contained in the greatest amount in the target object (in this case, passivation film 200). More specifically, the “main component” refers to the compound contained in the greatest amount in terms of volume ratio or mass ratio relative to other compounds in the object, as determined by quantitative or semi-quantitative analysis using X-ray diffraction (XRD) on the object.

The proportion of the main component (lanthanum yttrium oxide) in the passivation film 200 of the present embodiment is more than 50% by volume or by mass. The proportion may be more than 70%, more than 90%, or may be 100%.

The thickness of the passivation film 200 is appropriately adjusted depending on the duration for which resistance is required to be maintained and other factors. In the present embodiment, the passivation film 200 has a thickness of 15 μm or less.

The present inventors have been considering the use of a novel material for the passivation film 200 and further improvement in the resistance of the passivation film 200 against plasma. As a result of assessing and considering various materials, the present inventors have found that when the passivation film 200 is formed by using a material comprising lanthanum yttrium oxide as a main component as in the present embodiment, a sufficient resistance of the passivation film against plasma can be achieved.

The present inventors have also demonstrated that when a passivation film 200 is formed by using a material comprising lanthanum yttrium oxide as a main component, the resistance of the passivation film 200 against plasma varies depending on the crystal structure of the passivation film 200. Specifically, the inventors have found that as the proportion of hexagonal crystal structures in the passivation film 200 increases, the resistance of the passivation film 200 against plasma improves.

The present inventors prepared multiple samples of the structural member 10 with varying crystal structures for the passivation film 200, and assessed resistance against plasma for each passivation film 200. To evaluate the resistance of the passivation film 200 against plasma, the surface 210 of each passivation film 200 was exposed to a plasma environment using an inductively coupling plasma reactive ion etching (ICP-RIE) system (not shown). The following two sets of conditions were employed when exposing the surface 210 to the plasma environment.

Under the first condition, a 4-inch silicon wafer was held by an electrostatic chuck within the chamber of an inductively coupled plasma reactive ion etching system. A sample of the structural member 10, the subject of evaluation, was placed on the silicon wafer. Subsequently, the surface 210 of the passivation film 200 was exposed to a plasma environment by generating plasma within the chamber. SF₆ was used as the process gas, and supplied to the chamber at a flow rate of 100 sccm. The pressure in the chamber was adjusted to 0.5 Pa. The time of exposure was 30 minutes. The power output was set to 1,500 W for the ICP coil and 750 W for the bias. The plasma exposure test for the surface 210 of the passivation film 200, performed under the first conditions described above, is called the “First Standard Plasma Test” below. In the First Standard Plasma Test, by setting the bias output to 750 W as described above, the plasma is drawn toward the passivation film 200, and used for the etching of the passivation film 200.

Under the second condition, a 4-inch silicon wafer was held by an electrostatic chuck within the chamber of an inductively coupled plasma reactive ion etching system. A sample of the structural member 10, the subject of evaluation, was placed on the silicon wafer. Subsequently, the surface 210 of the passivation film 200 was exposed to a plasma environment by generating plasma within the chamber. SF₆ was used as the process gas, and supplied to the chamber at a flow rate of 100 sccm. The pressure in the chamber was adjusted to 0.5 Pa. The time of exposure was 60 minutes. The power output was set to 1, 500 W for the ICP coil, and the bias output was turned off (i.e., 0 W). The plasma exposure test for the surface 210 of the passivation film 200, performed under the second conditions described above, is called the “Second Standard Plasma Test” below. In the Second Standard Plasma Test, by turning off the bias output as described above, the plasma is not drawn toward the passivation film 200, and hardly used for the etching of the passivation film 200. The surface 210 of the passivation film 200 is simply exposed to non-directional plasma.

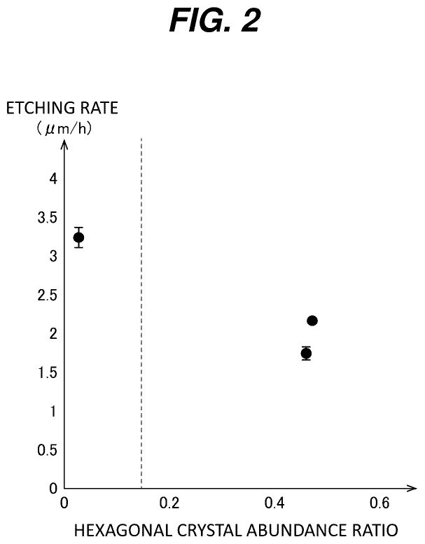

FIG. 2 shows the results of the First Standard Plasma Test described above conducted for each of the structural members 10. The “hexagonal crystal abundance ratio” on the horizontal axis of the graph in FIG. 2 is an indicator of the proportion of the hexagonal crystal structure in the passivation film 200. When no hexagonal crystal structures exist in the passivation film 200, the hexagonal crystal abundance ratio is 0. When all crystals forming the passivation film 200 are hexagonal, the hexagonal crystal abundance ratio is 1. Specific definitions and calculation methods of the hexagonal crystal abundance ratio will be described later.

The vertical axis of the graph in FIG. 2 represents the etching rate in the First Standard Plasma Test, specifically the depth to which the passivation film 200 is etched per unit time, expressed in units of μm/h. The higher the resistance of the passivation film 200 against plasma, the smaller the etching rate of the passivation film 200. The etching rate may be used as an indicator of the resistance of the passivation film 200 against plasma.

FIG. 2 shows the etching rates, with error bars, obtained from the First Standard Plasma Test for three samples with varying hexagonal crystal abundance ratios of the passivation film 200. For the sample with a hexagonal crystal abundance ratio of 0.03, the etching rate was 3.24 μm/hour. For the sample with a hexagonal crystal abundance ratio of 0.46, the etching rate was 1.74 μm/hour. For the sample with a hexagonal crystal abundance ratio of 0.47, the etching rate was 2.17 μm/hour.

As FIG. 2 clearly shows, the larger the hexagonal crystal abundance ratio value of the passivation film 200, the smaller the etching rate of the passivation film 200. For the passivation films 200 with a hexagonal crystal abundance ratio greater than 0.15, i.e., to the right of the dotted line in FIG. 2, the etching rate is sufficiently low, and sufficient resistance against plasma was verified.

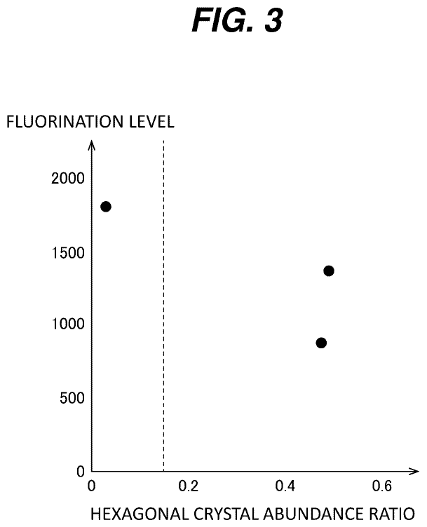

FIG. 3 shows the results of the Second Standard Plasma Test described above conducted for each of the structural members 10. The horizontal axis of the graph in FIG. 3 represents the hexagonal crystal abundance ratio as in FIG. 2. The samples prepared for the Second Standard Plasma Test were prepared by the same method as for the samples prepared for the First Standard Plasma Test. Therefore, the hexagonal crystal abundance ratio value of each sample shown in FIG. 3 is the same as the hexagonal crystal abundance ratio value of each sample shown in FIG. 2.

The vertical axis of the graph in FIG. 3 represents the fluorination level of the passivation film 200 after the Second Standard Plasma Test. The “fluorination level” is an indicator of how deep fluorine atoms, which are part of plasma, penetrate into the interior of the passivation film 200. Specific measurement methods of the fluorination level are as follows.

First, while sputtering the surface 210 of the passivation film 200 after the Second Standard Plasma Test using argon, the amount of fluorine atoms present on the surface 210 was continuously measured by X-ray photoelectron spectroscopy (XPS). The measurement was performed for 145 seconds. During the measurement, the proportion of the measured argon concentration in the overall composition (in %) was calculated at each time point, and the integrated value of these proportions was defined as the “fluorination level” of the sample. The higher the resistance of the passivation film 200 against plasma, the smaller the value of the fluorination level calculated as described above. Like the etching rate described above, the fluorination level may be used as an indicator of the resistance of the passivation film 200 against plasma.

The fluorination level for the sample with a hexagonal crystal abundance ratio of 0.03 was 1802. The fluorination level for the sample with a hexagonal crystal abundance ratio of 0.46 was 869. The fluorination level for the sample with a hexagonal crystal abundance ratio of 0.47 was 1379.

As FIG. 3 clearly shows, the larger the hexagonal crystal abundance ratio value of the passivation film 200, the smaller the fluorination level of the passivation film 200. For the passivation film 200 with a hexagonal crystal abundance ratio greater than 0.15, i.e., to the right of the dotted line in FIG. 3, the fluorine level is sufficiently low, and sufficient resistance against plasma was verified.

The calculation method of the hexagonal crystal abundance ratio will be described. The hexagonal crystal abundance ratio is calculated from the results of the analysis of the crystal structure of the passivation film 200 using X-ray diffraction.

The lattice constant of the passivation film 200 was measured using the following method. First, X-ray diffraction (XRD) was performed on the passivation film 200 formed on the substrate 100 by out-of-plane measurement using a 0-20 scan.

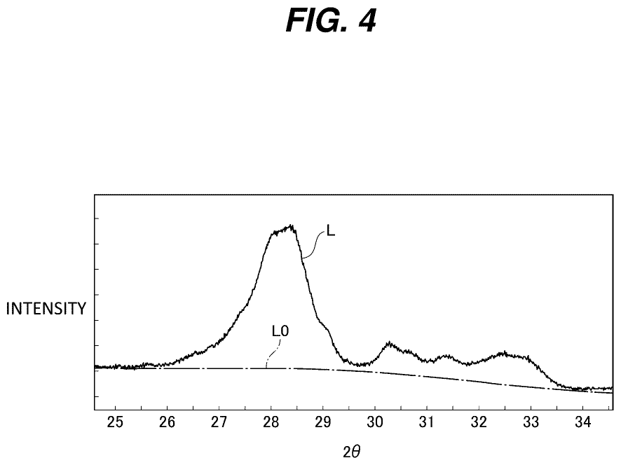

The line L10 in FIG. 4 is an example of the diffraction patterns obtained by analyzing the passivation films 200 using X-ray diffraction. This diffraction pattern is also referred to as “the measured diffraction pattern L10” below. A plurality of peaks are observed in the measured diffraction pattern L10, and each peak corresponds to the crystal structure of the material of the passivation film 200. For example, the diffraction angles 2θ corresponding to the maximum of each peak are characteristic of the crystal structure of the passivation film 200. The height of each peak corresponds to the proportion of the crystal structure associated with the diffraction angle 2θ in the passivation film 200.

The “maximum intensity” of each peak may be used as is, as represented by the maximum intensity on the vertical axis of FIG. 4. However, to determine the proportion of the hexagonal crystal structure in the passivation film 200 with higher accuracy, the following method is used to obtain the maximum intensity of each peak in the present embodiment.

The dash-dotted line L0 shown in FIG. 4 represents the background intensity in the absence of peaks. The profile of the dash-dotted line L0 can be inferred, for example, from the overall diffraction pattern.

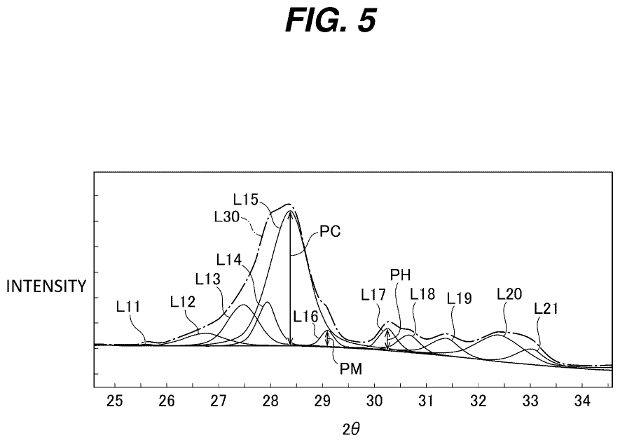

The line L11 shown in FIG. 5 represents a hypothetical diffraction pattern obtained by adding only the peak with the maximum at a diffraction angle 2θ of 25.616° to the background represented by the dash-dotted line L0 in FIG. 4. The same applies to the lines L12 to L21 shown in FIG. 5, each line representing a hypothetical diffraction pattern obtained by adding only the peak with the maximum at a specific diffraction angle 2θ to the background.

The diffraction angle 2θ of the peak of line L12 is 26.730°; the diffraction angle 2θ of the peak of line L13 is 27.460°; the diffraction angle 2θ of the peak of line L14 is 27.911°; the diffraction angle 2θ of the peak of line L15 is 28.356°; the diffraction angle 2θ of the peak of line L16 is 29.070°; the diffraction angle 2θ of the peak of line L17 is 30.231°; the diffraction angle 2θ of the peak of line L18 is 30.632°; the diffraction angle 2θ of the peak of line L19 is 31.328°; the diffraction angle 2θ of the peak of line L20 is 32.380°; and the diffraction angle 2θ of the peak of line L21 is 32.973°.

The dash-dotted line 30 shown in FIG. 5 is a diffraction pattern obtained by combining all the hypothetical diffraction patterns represented by the lines L11 to L21. This diffraction pattern is also referred to as “approximated diffraction pattern L30” below. When combining multiple hypothetical diffraction patterns, redundant background intensities are not added.

The hypothetical diffraction patterns represented by the lines L11 to L21 are individually adjusted so that the profile of the approximated diffraction pattern L30 obtained by combining them substantially matches the measured diffraction pattern L10 shown in FIG. 4. In other words, by individually adjusting the diffraction angle 2θ at which the peak reaches the maximum and the height of the peak relative to the background for each line such as L11, the profile of the approximated diffraction pattern L30 is brought closer to the measured diffraction pattern L10. When the two profiles substantially match as a result of such adjustments, each hypothetical diffraction pattern represented by the lines L11 to L21 corresponds to a profile decomposed from the measured diffraction pattern L10 at each diffraction angle 2θ. Such a process may be performed manually while observing the profile of the approximated diffraction pattern L30, or may be performed automatically using the software functionality.

When the material of the passivation film 200 is lanthanum yttrium oxide, the diffraction angle 2θ of the peak attributed to the (222) plane of the cubic crystal structure is known to be approximately 28.3°. Thus, in the example shown in FIG. 5, the peak attributed to the (222) plane of the cubic crystal structure can be inferred as the peak represented by the line L15. The maximum intensity of the peak, in other words, the maximum intensity of the peak relative to the background, is also referred to as the “maximum intensity PC” below.

When the material of the passivation film 200 is lanthanum yttrium oxide, the diffraction angle 2θ of the peak attributed to the (−402) plane of the monoclinic crystal structure is known to be approximately 29.3°. Thus, in the example shown in FIG. 5, the peak attributed to the (−402) plane of the monoclinic crystal structure can be inferred as the peak represented by the line L16. The maximum intensity of the peak, in other words, the maximum intensity of the peak relative to the background, is also referred to as the “maximum intensity PM” below.

When the material of the passivation film 200 is lanthanum yttrium oxide, the diffraction angle 2θ of the peak attributed to the (101) plane of the hexagonal crystal structure is known to be approximately 29.8°. Thus, in the example shown in FIG. 5, the peak attributed to the (101) plane of the hexagonal crystal structure can be inferred as the peak represented by the line L17. The maximum intensity of the peak, in other words, the maximum intensity of the peak relative to the background, is also referred to as the “maximum intensity PH” below.

Using the maximum intensity values PC, PM, and PH calculated by the method described above, the hexagonal crystal abundance ratio is determined by the following equation (1).

$$Hexagonal crystal abundance ratio = PH / ( PC + PM + PH ) \qquad ( 1 )$$

As described above, the maximum intensity PC refers to the maximum intensity of the peak attributed to the (222) plane of the cubic crystal structure. The maximum intensity PM refers to the maximum intensity of the peak attributed to the (−402) plane of the monoclinic crystal structure. The maximum intensity PH refers to the maximum intensity of the peak attributed to the (101) plane of the hexagonal crystal structure. Therefore, the hexagonal crystal abundance ratio determined by the above equation (1) can be used as an indicator of the proportion of the hexagonal crystal structure in the passivation film 200. As described with reference to FIG. 2 and FIG. 3, when the hexagonal crystal abundance ratio=PH/(PC+PM+PH)>0.15 is satisfied for the passivation film 200, a sufficient resistance against plasma is achieved in the passivation film 200.

The patterns shown in FIG. 4 and FIG. 5 are examples for illustrating the definition and the calculation method of the hexagonal crystal abundance ratio and do not correspond to the passivation film 200 of the present embodiment.

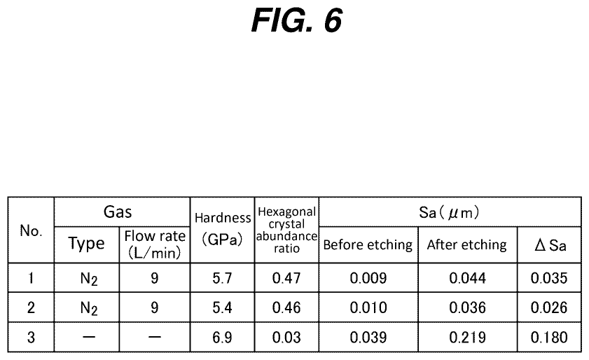

The method and other conditions for producing the samples used for obtaining the data shown in FIG. 2 and FIG. 3 will be described with reference to FIG. 6. Samples No. 1 and No. 2 in FIG. 6 are samples having a passivation film 200 formed on the surface 110 of a substrate 100 under substantially the same conditions. Sample No. 3 is a sintered body of LaYO₃, prepared as Comparative Example for the samples described above.

All of the passivation film 200 samples No. 1 and 2 were formed by using an aerosol deposition method. As is well known, in the aerosol deposition method, fine particles constituting the passivation film 200 are dispersed in a gas to form an aerosol, which is then sprayed from a nozzle toward the surface 110 to collide with it. At the surface 110, fine particles are deformed or fractured upon collision, bonding and depositing progressively to form the passivation film 200. FIG. 6 shows the type of the gas described above used in the film-forming of the samples and the flow rate in spraying the gas from the nozzle. A LaYO₃ powder was used as the “fine particles” described above.

The “hardness” shown in FIG. 6 represents the measured value of the indentation hardness of the passivation film 200, expressed in units of GPa. The indentation hardness of the passivation film 200 was measured by performing a nanoindentation test on the surface 210 of the passivation film 200 formed on the substrate 100 (for Sample No. 3, on the surface of the sintered body). The indentation hardness of the surface 210 was measured at several sites using a Berkovich indenter with an indentation depth fixed at 200 nm. The respective measurement sites were portions of the surface 210 free of scratches or pits. Provided that the surface 210 is polished to achieve a smooth finish before indentation hardness testing, measurements can be conducted with enhanced precision. The number of measurement sites was 10 or more, and the average of the indentation hardness values obtained from each site was determined as the indentation hardness of the passivation film 200. For specific testing methods, analytical methods, procedures for verifying testing device performance, and requirements for reference samples, methods specified in ISO14577 were employed.

Samples No. 1, 2, and 3 were each prepared in pairs. The First Standard Plasma Test was conducted on one of each pair, yielding the results shown in FIG. 2. The Second Standard Plasma Test was conducted on the other, yielding the results shown in FIG. 3. The hexagonal crystal abundance ratio in the passivation film 200 of Sample No. 1 was calculated to be 0.47. The hexagonal crystal abundance ratio in the passivation film 200 of Sample No. 2 was calculated to be 0.46. The hexagonal crystal abundance ratio of the sintered body of Sample No. 3 was calculated to be 0.03. As described above, the hexagonal crystal abundance ratio was more than 0.15 in Samples No. 1 and No. 2, and high resistance against plasma was verified.

The present inventors measured the arithmetic mean height (Sa) of the surface 210 for Samples No. 1 and 2 before and after conducting the First Standard Plasma Test. In the “Before etching” column of the table in FIG. 6, the arithmetic mean height of the surface 210, measured prior to the First Standard Plasma Test, is shown in μm. In the “After etching” column, the arithmetic mean height of the surface 210, measured after the First Standard Plasma Test, is shown in μm. In the “ΔSa” column, the difference in the above two arithmetic mean heights is shown. Namely, the variation in the arithmetic mean height of the surface 210 after conducting the First Standard Plasma Test is shown in μm. The method specified in ISO25178 was used as the measurement method of the arithmetic mean height.

For Sample No. 3, in which the hexagonal crystal abundance ratio of the surface of the sintered body is less than 0.15, the variation in the arithmetic mean height (ΔSa) of the surface 210 after conducting the First Standard Plasma Test significantly exceeds 0.05 μm. On the other hand, for Samples No. 1 and 2, in which the hexagonal crystal abundance ratio of the passivation film 200 is more than 0.15, the variation in the arithmetic mean height (ΔSa) of the surface 210 after conducting the First Standard Plasma Test is less than 0.05 μm.

The above results confirmed that in Samples No. 1 and 2 having a hexagonal crystal abundance ratio of the passivation film 200 of larger than 0.15, the shape change of the surface 210 due to etching was small.

The present embodiment has been described with reference to examples. However, the present disclosure is not limited to these examples. Modifications made to the foregoing examples by those skilled in the art fall within the scope of the present disclosure, provided that they retain the characteristics of the present disclosure. The elements of the foregoing examples, including their configurations, conditions, shapes, and the like, are not limited to those illustrated and can be modified as appropriate. The elements of the foregoing examples can be variously combined, provided that no technical contradiction arises.

What is claimed is:

1. A structural member comprising:
a substrate, and
a passivation film covering a surface of the substrate,
wherein the passivation film comprises lanthanum yttrium oxide as a main component.

2. The structural member according to claim 1, wherein, in a diffraction pattern obtained by analyzing the passivation film using X-ray diffraction,
PH/(PC+PM+PH)>0.15 is satisfied,
where PC represents a maximum intensity of a peak attributed to the (222) plane of a cubic crystal structure,
PM represents a maximum intensity of a peak attributed to the (−402) plane of a monoclinic crystal structure, and
PH represents a maximum intensity of a peak attributed to the (101) plane of a hexagonal crystal structure.

3. The structural member according to claim 1, wherein the passivation film is formed by using an aerosol deposition method.
